(19) United States
(12) Patent Application Publication
(10) Pub. No.: US 2014/0048955 A1
(43) Pub. Date: Feb. 20, 2014

(54) SEMICONDUCTOR ASSEMBLY BOARD WITH BACK-TO-BACK EMBEDDED SEMICONDUCTOR DEVICES AND BUILT-IN STOPPERS

(71) Applicant: Bridge Semiconductor Corporation, Taipei City (TW)

(72) Inventors: Charles W.C. LIN, Singapore (SG); Chia-Chung WANG, Hsinchu (TW)

(73) Assignee: Bridge Semiconductor Corporation, Taipei CIty (TW)

(21) Appl. No.: 14/062,939

(22) Filed: Oct. 25, 2013

Related U.S. Application Data
(63) Continuation-in-part of application No. 13/733,226, filed on Jan. 3, 2013.
Application No. 13/733,226 is a continuation-in-part of application No. 13/738,314, filed on Jan. 10, 2013.
Application No. 13/738,314 is a continuation-in-part of application No. 13/753,570, filed on Jan. 30, 2013.
Application No. 13/753,570 is a continuation-in-part of application No. 13/753,589, filed on Jan. 30, 2013.
Application No. 13/753,570 is a continuation-in-part of application No. 13/733,226, filed on Jan. 3, 2013.
Application No. 13/733,226 is a continuation-in-part of application No. 13/738,314, filed on Jan. 10, 2013.
Application No. 13/753,589 is a continuation-in-part of application No. 13/733,226, filed on Jan. 3, 2013.
Application No. 13/733,226 is a continuation-in-part of application No. 13/738,314, filed on Jan. 10, 2013.
(60) Provisional application No. 61/721,653, filed on Nov. 2, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.

(51) Int. Cl. H01L 23/48

(52) U.S. Cl. CPC H01L 23/481
USPC 257/774

(57) ABSTRACT

In a preferred embodiment, a semiconductor assembly board with back-to-back embedded devices and built-in stoppers includes an intermediate layer, a first stopper, a first semiconductor device, a first core layer, a second stopper, a second semiconductor device, a second core layer, a first build-up circuitry, a second build-up circuitry and a plated through hole. The first and second semiconductor devices are mounted on opposite surfaces of the intermediate layer using the first and second stoppers as placement guides that are laterally aligned with peripheral edges of the first and second semiconductor devices. The first and second core layers laterally cover the first and second semiconductor devices. The first and second build-up circuitries cover the semiconductor devices and the core layers in the opposite vertical directions and provide signal routing for the first and second semiconductor devices.

### CROSS REFERENCE TO RELATED APPLICATION

This application is a continuation-in-part of U.S. application Ser. No. 13/733,226 filed Jan. 3, 2013, a continuation-in-part of U.S. application Ser. No. 13/738,314 filed Jan. 10, 2013, a continuation-in-part of U.S. application Ser. No. 13/753,570 filed Jan. 30, 2013 and a continuation-in-part of U.S. application Ser. No. 13/753,589 filed Jan. 30, 2013, each of which is incorporated by reference. This application also claims the benefit of filing date of U.S. Provisional Application Ser. No. 61/721,653 filed Nov. 2, 2012.

U.S. application Ser. No. 13/733,226 filed Jan. 3, 2013, U.S. application Ser. No. 13/738,314 filed Jan. 10, 2013, U.S. application Ser. No. 13/753,570 filed Jan. 30, 2013 and U.S. application Ser. No. 13/753,589 filed Jan. 30, 2013 all claim the benefit of filing date of U.S. Provisional Application Ser. No. 61/682,801 filed Aug. 14, 2012.

U.S. application Ser. No. 13/753,570 filed Jan. 30, 2013 is a continuation-in-part of U.S. application Ser. No. 13/733,226 filed Jan. 3, 2013 and a continuation-in-part of U.S. application Ser. No. 13/738,314 filed Jan. 10, 2013. U.S. application Ser. No. 13/753,589 filed Jan. 30, 2013 is a continuation-in-part of U.S. application Ser. No. 13/733,226 filed Jan. 3, 2013 and a continuation-in-part of U.S. application Ser. No. 13/738,314 filed Jan. 10, 2013.

### BACKGROUND OF THE INVENTION

1. Field of the Invention

The present invention relates to a semiconductor assembly board with back-to-back embedded devices, and more particularly to a semiconductor assembly board which includes built-in stoppers as placement guides for back-to-back embedded devices.

2. Description of Related Art

As market trend demands for thinner, smarter and cheaper portable electronics, semiconductor devices for use in these equipments are required to further shrink their size and improve electrical performances at lower cost. Among all the efforts, embedding or built-in semiconductor chip in printed wiring board to form a module assembly is considered the most effective approach since it can drastically reduce the overall weight, thickness and improve electrical performance through a shorten interconnect distance.

However, the attempt of embedding chip in a wiring board can encounter many problems. For example, the chip to be embedded is known to vertically and laterally shift during die attach and encapsulation/lamination processes due to thermal characteristics of plastic materials. The CTE mismatch between metal, dielectric and silicon at various stages of thermal treatment can result in misalignment of the build-up interconnect structure to be deposited thereon. U.S. Pat. No. 7,935,893 to Tanaka et. al., U.S. Pat. No. 7,944,039 to Aral and U.S. Pat. No. 7,405,103 to Chang disclose various alignment methods to address manufacturing yield concern. None of these approaches offers a proper solution or effective method for controlling die movement because the underneath adhesive will reflow during curing and therefore dislocates the attached die from the pre-determined location even a highly precise alignment mark and equipment are applied. U.S. Patent Application 2010/0184256 to Chino discloses a resin sealing method to fix the semiconductor device adhered to the adhesive layer formed on the support body. This approach may be effective in controlling die from further movement during die sealing process, it does not provide any control or adjustment during die attach process and the mis-registration is unavoidable due to die attach adhesive reflows. U.S. Pat. No. 7,674,986 to Chang et. al., U.S. Pat. No. 7,656,040 to Hsu et. al., and U.S. Pat. No. 7,656,015 to Wang et. al., disclose various package structures with chip stack structure to address ultra-high packing density requirements. Low manufacturing yield can be compounded if the die dislocation problem is not completely resolved.

### SUMMARY OF THE INVENTION

The present invention has been developed in view of such a situation, and an object thereof is to provide a semiconductor assembly board in which semiconductor devices are back-to-back affixed on opposite surfaces of an intermediate layer at predetermined location defined by stoppers and the signal routings for the semiconductor devices are provided by build-up circuitries. Accordingly, the present invention provides a semiconductor assembly board that includes an intermediate layer, a first stopper, a first semiconductor device, a first core layer, a second stopper, a second semiconductor device, a second core layer, a first build-up circuitry, a second build-up circuitry and a plated through hole.

In a preferred embodiment, the first and second stoppers respectively serve as placement guides for the first and second semiconductor devices back-to-back mounted on opposite surfaces of the intermediate layer. The first and second stoppers are respectively in close proximity to and laterally aligned with peripheral edges of the first and second semiconductor devices in lateral directions. The first and second core layers laterally cover the first and second semiconductor devices, respectively. The first and second build-up circuitries provide signal routing for the first and second semiconductor devices.

The intermediate layer can be a single layer structure or a multi-layer structure. For instance, the intermediate layer can be a dielectric layer or a metal layer or a laminated substrate that includes a first metal layer, a second metal layer and a dielectric layer sandwiched between the first metal layer and the second metal layer.

The first and second stoppers can contact and extend from the intermediate layer in the first and second vertical directions and be in close proximity to and laterally aligned with peripheral edges of the first and second semiconductor devices, respectively. The first and second stoppers can be made of a metal, a photosensitive plastic material or non-photosensitive material. For instance, the first and second stoppers can consist essentially of copper, aluminum, nickel, iron, tin or their alloys. The first and second stoppers can also consist of epoxy or polyimide. Further, the first and second stoppers can have patterns against undesirable movement of the first and second semiconductor devices, respectively. For instance, the first and second stoppers can individually include a continuous or discontinuous strip or an array of posts. Specifically, the first and second stoppers can be laterally aligned with four lateral surfaces of the first and second semiconductor devices to stop the lateral displacement of the first and second semiconductor devices. For instance, the first and second stoppers can be aligned along and conform to four sides, two diagonal corners or four corners of the first and second semiconductor devices, and gaps in between the first semiconductor device and the first stopper and between the second semiconductor device and the second stopper preferably is in a range of about 0.001 to 1 mm. As a result, the first and second stoppers located beyond the first and second semiconductor devices can prevent the location error of the first and second semiconductor devices from exceeding the maximum acceptable error limit. Besides, the first and second stoppers preferably have a height in a range of 10-200 microns.

The first and second semiconductor devices individually include an active surface with a contact pad thereon and an inactive surface opposite to the active surface. The active surface of the first semiconductor device faces the first vertical direction away from the intermediate layer, and the inactive surface of the first semiconductor device faces the second vertical direction toward the intermediate layer. The active surface of the second semiconductor device faces the second vertical direction away from the intermediate layer, and the inactive surface of the second semiconductor device faces the first vertical direction toward the intermediate layer. Further, the first and second semiconductor devices can be mounted on the intermediate layer by an adhesive. For instant, a first adhesive can contact and be sandwiched between the intermediate layer and the inactive surface of the first semiconductor device, while a second adhesive can contact and be sandwiched between the intermediate layer and the inactive surface of the second semiconductor device. In any case, the first adhesive can be coplanar with the first stopper in the second vertical direction and lower than the first stopper in the first vertical direction, while the second adhesive can be coplanar with the second stopper in the first vertical direction and lower than the second stopper in the second vertical direction. As the first and second adhesives underneath the first and second semiconductor devices are respectively lower than the first and second stoppers in the first and second vertical directions, the first and second stoppers can stop the undesirable movement of the first and second semiconductor devices due to adhesive curing. For instance, in the aspect of using a dielectric layer or a metal layer as the intermediate layer, the first semiconductor device is mounted on the dielectric layer or the metal layer from the first vertical direction by the first adhesive using the first stopper as a placement guide that extends from the dielectric layer or the metal layer in the first vertical direction. As a result, the first semiconductor device can be accurately confined at predetermined location by the first stopper that extends beyond the inactive surface of the first semiconductor device and is lower than the active surface of the first semiconductor device in the first second vertical direction. Likewise, the second semiconductor device can be mounted on the dielectric layer or the metal layer from the second vertical direction by the second adhesive using the second stopper as a placement guide that extends from the dielectric layer or the metal layer in the second vertical direction. As a result, the second semiconductor device can be accurately confined at predetermined location by the second stopper that extends beyond the inactive surface of the second semiconductor device and is lower than the active surface of the second semiconductor device in the second vertical direction. As for another aspect of using a laminate substrate as the intermediate layer, the first semiconductor device can be mounted on a first metal layer of the laminate substrate by the first adhesive using the first stopper as a placement guide that extends from the first metal layer of the laminate substrate and extends beyond the inactive surface of the first semiconductor device in the first vertical direction. Likewise, the second semiconductor device can be mounted on a second metal layer of the laminate substrate by the second adhesive using the second stopper as a placement guide that extends from the second metal layer of the laminate substrate and extends beyond the inactive surface of the second semiconductor device in the second vertical direction. The first metal layer and the second metal layer can be spaced from one another by a dielectric layer and serve as vertical electromagnetic shields which can effectively shield the first and second semiconductor devices from electromagnetic interference (EMI).

The first core layer can contact and surround and conformally coat the sidewall of the first semiconductor device and the first stopper, cover the first stopper and the intermediate layer in the first vertical direction, and extend laterally from the first semiconductor device and the first stopper to peripheral edges of the assembly board. Likewise, the second core layer can contact and surround and conformally coat the sidewall of the second semiconductor device and the second stopper, cover the second stopper and the intermediate layer in the second vertical direction, and extend laterally from the second semiconductor device and the second stopper to peripheral edges of the assembly board. In any case, the first and second core layers laterally cover the first and second semiconductor devices and the first and second stoppers, respectively. The first and second core layers can be made of pre-preg materials such as epoxy, BT, polyimide and other kind of resins or resin/glass composite.

The first build-up circuitry covers the first semiconductor device and the first core layer from the first vertical direction and is electrically connected to the contact pad of the first semiconductor device. The first build-up circuitry can include a first insulating layer and one or more first conductive traces. For instance, the first insulating layer covers the first semiconductor device and the first core layer in the first vertical direction and can extend to peripheral edges of the assembly board, and the first conductive traces extend from the first insulating layer in the first vertical direction. The first insulating layer can include one or more first via openings that are disposed adjacent to one or more contact pads of the first semiconductor device. One or more first conductive traces extend from the first insulating layer in the first vertical direction and extend laterally on the first insulating layer and extend into the first via openings in the second vertical direction to form one or more first conductive vias, thereby providing signal routing for the contact pads of the first semiconductor device. As the first conductive traces can directly contact the contact pads of the first semiconductor device, the electrical connection between the first semiconductor device and the first build-up circuitry can be devoid of solder.

The second build-up circuitry covers the second semiconductor device and the second core layer from the second vertical direction and is electrically connected to the contact pad of the second semiconductor device. The second build-up circuitry can include a second insulating layer and one or more second conductive traces. For instance, the second insulating layer covers the second semiconductor device and the second core layer in the second vertical direction and can extend to peripheral edges of the assembly board, and the second conductive traces extend from the second insulating layer in the second vertical direction. The second insulating layer can include one or more second via openings that are disposed adjacent to one or more contact pads of the second semiconductor device. One or more second conductive traces extend from the second insulating layer in the second vertical direction and extend laterally on the second insulating layer and extend into the second via openings in the first vertical direction to form one or more second conductive vias, thereby providing signal routing for the contact pads of the second semiconductor device. As the second conductive traces can directly contact the contact pads of the second semiconductor device, the electrical connection between the second semiconductor device and the second build-up circuitry can be devoid of solder.

The first and second build-up circuitry can include additional layers of dielectric (such as a third insulating layer on the first insulating layer and first conductive traces, a fourth insulating layer on the second insulating layer and second conductive traces), additional layers of via openings (such as third via openings in the third insulating layer, fourth via openings in the fourth insulating layer), and additional layers of conductive traces (such as third conductive traces on the third insulating layer, fourth conductive traces on the fourth insulating layer) if needed for further signal routing. The outmost conductive traces of the first and second build-up circuitries can respectively include one or more first and second interconnect pads to provide electrical contacts for an electronic device such as a semiconductor chip, a plastic package or another semiconductor assembly. The first interconnect pads can include an exposed contact surface that faces in the first vertical direction, while the second interconnect pads can include an exposed contact surface that faces in the second vertical direction. As a result, the assembly board can include electrical contacts (i.e. the first and second interconnect pads) that are electrically connected to one another and located on opposite surfaces that face in opposite vertical directions, so that the assembly board is stackable and electronic devices can be electrically connected to the assembly board using a wide variety of connection media including wire bonding or solder bumps as the electrical contacts.

The plated through hole can provide signal routing in the vertical direction between the first build-up circuitry and the second build-up circuitry. For instance, the plated though hole at a first end can extend to and be electrically connected to an outer or inner conductive layer of the first build-up circuitry and at a second end can extend to and be electrically connected to an outer or inner conductive layer of the second build-up circuitry. In any case, the plated through hole extends vertically through the first core layer, the intermediate layer and the second core layer to provide an electrical connection between the first and second build-up circuitries.

The present invention also provides a method of making a semiconductor assembly board with back-to-back embedded semiconductor devices, comprising: forming a first stopper on an intermediate layer that extends from the intermediate layer in a first vertical direction; mounting a first semiconductor device on the intermediate layer using the first stopper as a placement guide for the first semiconductor device that includes an active surface with a contact pad thereon and an inactive surface, wherein the active surface faces the first vertical direction away the intermediate layer, the inactive surface faces a second vertical direction opposite the first vertical direction toward the intermediate layer, and the first stopper is located in close proximity to and laterally aligned with peripheral edges of the first semiconductor device in lateral directions orthogonal to the vertical directions; providing a first core layer that laterally covers the first semiconductor device and the first stopper; forming a second stopper on the intermediate layer that extends from the intermediate layer in the second vertical direction; mounting a second semiconductor device on the intermediate layer using the second stopper as a placement guide for the second semiconductor device that includes an active surface with a contact pad thereon and an inactive surface, wherein the active surface faces the second vertical direction away the intermediate layer, the inactive surface faces the first vertical direction toward the intermediate layer, and the second stopper is located in close proximity to and laterally aligned with peripheral edges of the second semiconductor device in lateral directions orthogonal to the vertical directions; providing a second core layer that laterally covers the second semiconductor device and the second stopper; forming a first build-up circuitry that covers the first semiconductor device and the first core layer in the first vertical direction and is electrically connected to the contact pad of the first semiconductor device through a first conductive via; forming a second build-up circuitry that covers the second semiconductor device and the second core layer in the second vertical direction and is electrically connected to the contact pad of the second semiconductor device through a second conductive via; and providing a plated through hole that extends through the first core layer, the intermediate later and the second core layer to provide an electrical connection between the first build-up circuitry and the second build-up circuitry.

The first and second stoppers can be formed by patterning of a metal layer on the intermediate layer or by pattern deposition of a metal or a plastic material on the intermediate layer and can have the same or different patterns. For instance, forming the first stopper and the second stopper on the intermediate layer can include: providing a laminate substrate that includes a first metal layer, a second metal layer and a dielectric layer sandwiched between the first metal layer and the second metal layer; then removing a selected portion of the first metal layer to form the first stopper; and removing a selected portion of the second metal layer to form the second stopper. Alternatively, forming the first stopper and the second stopper on the intermediate layer can include: providing a laminate substrate that includes a first metal layer, a second metal layer and a dielectric layer sandwiched between the first metal layer and the second metal layer; then removing a selected portion of the first metal layer to form a first recessed portion; depositing a first plastic material into the first recessed portion as the first stopper; removing a remaining portion of the first metal layer; removing a selected portion of the second metal layer to form a second recessed portion; depositing a second plastic material into the second recessed portion as the second stopper; and removing a remaining portion of the second metal layer. Accordingly, the first and second stoppers can serve as placement guides for semiconductor devices back-to-back mounted on the dielectric layer as the intermediate layer. As another aspect, forming the first stopper and the second stopper on the intermediate layer can include: providing a metal layer; then pattern depositing the first stopper on the metal layer; and pattern depositing the second stopper on the metal layer. Alternatively, forming the first stopper and the second stopper on the intermediate layer can include: providing a laminate substrate that includes a first metal layer, a second metal layer and a dielectric layer sandwiched between the first metal layer and the second metal layer; then pattern depositing the first stopper on the first metal layer; and pattern depositing the second stopper on the second metal layer. Accordingly, the first and second stoppers can serve as placement guides for semiconductor devices back-to-back mounted on the metal layer as the intermediate layer or on the first and second metal layers of the laminate layer as the intermediate layer.

Forming the first build-up circuitry and the second build-up circuitry can include: providing a first insulating layer that covers the first semiconductor device and the first core layer in the first vertical direction; providing a second insulating layer that covers the second semiconductor device and the second core layer in the second vertical direction; forming one or more first via openings that extend through the first insulating layer and are aligned with one or more contact pads of the first semiconductor device; forming one or more second via openings that extend through the second insulating layer and are aligned with one or more contact pads of the second semiconductor device; forming one or more first conductive traces that extend from the first insulating layer in the first vertical direction and extend laterally on the first insulating layer and extend through the first via openings in the second vertical direction to form one or more first conductive vias in direct contact with the contact pads of the first semiconductor device; and forming one or more second conductive trace that extend from the second insulating layer in the second vertical direction and extend laterally on the second insulating layer and extend through the second via openings in the first vertical direction to form one or more second conductive vias in direct contact with the contact pads of the second semiconductor device.

The first and second via openings can be simultaneously formed and can have the same size, and the first and second conductive traces can be simultaneously deposited and patterned. The first insulating layers and conductive traces can have flat elongated surfaces that face in the first vertical direction, while the second insulating layers and conductive traces can have flat elongated surfaces that face in the second vertical direction.

Providing the plated through-hole can include forming a through hole that extends through the first core layer, the intermediate layer and the second core layer in the vertical directions, and then depositing a connecting layer on an inner sidewall of the through hole.

The plated through hole can be provided during providing the first build-up circuitry and the second build-up circuitry. For instance, providing the plated through hole can include forming a through hole that extends through the first core layer, the intermediate layer, the second core layer and the insulating layers (e.g. extends through the first and second insulating layers, or further extends through the first, second and additional insulating layers) in the vertical directions after providing the insulating layers; and then depositing a connecting layer on an inner sidewall of the through hole during depositing the conductive traces (e.g. the first conductive trace/the second conductive trace or the additional conductive traces).

The insulating layers can be deposited by numerous techniques including film lamination, roll coating, spin coating and spray-on deposition. The via openings can be formed through the insulating layers by numerous techniques including laser drilling, plasma etching and photolithography. The conductive traces can be formed by depositing a plated layer that covers the insulating layer and extends through the via opening and then removing selected portions of the plated layer using an etch mask that defines the conductive trace. The plated layers and the connecting layer can be deposited by numerous techniques including electroplating, electroless plating, evaporating, sputtering, and their combinations as a single layer or multiple layers. The plated layers can be patterned by numerous techniques including wet etching, electro-chemical etching, laser-assist etching, and their combinations to define the conductive traces.

Unless specific descriptions or using the term “then” between steps or steps necessarily occurring in a certain order, the sequence of the above-mentioned steps is not limited to that set forth above and may be changed or reordered according to desired design.

The present invention has numerous advantages. The stopper can accurately confine the placement location of the semiconductor device and avoid the electrical connection failure between the semiconductor device and the build-up circuitry resulted from the lateral displacement of the semiconductor device, thereby improving the manufacturing yield greatly. The back-to-back embedded structure reduces total thickness of the assembly. The direct electrical connection without solder between the semiconductor device and the build-up circuitry is advantageous to high I/O and high performance. Vertical connection for 3D stacking through plated through holes and build-up layers reduces cost and ensures reliability. The assembly board made by this method is reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-9 are cross-sectional views showing a method of making an assembly board that includes an intermediate layer, a first stopper, a first semiconductor device, a first core layer, a second stopper, a second semiconductor device, a second core layer, dual build-up circuitries and plated through holes in accordance with an embodiment of the present invention, in which FIGS. 2A, 2A′ and 3A are top perspective views corresponding to FIGS. 2, 2′ and 3, and FIGS. 2B-2E are top perspective views of other various patterns of the stopper for reference;

FIGS. 10-19 are cross-sectional views showing a method of making another assembly board in which embedded semiconductor devices are back-to-back mounted on a laminate substrate that includes metal layers as vertical EMI shields between the semiconductor devices in accordance with another embodiment of the present invention; and

FIGS. 20-27 are cross-sectional views showing a method of making yet another assembly board in which embedded semiconductor devices are back-to-back mounted on a metal layer as a vertical EMI shield between the semiconductor devices in accordance with yet another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

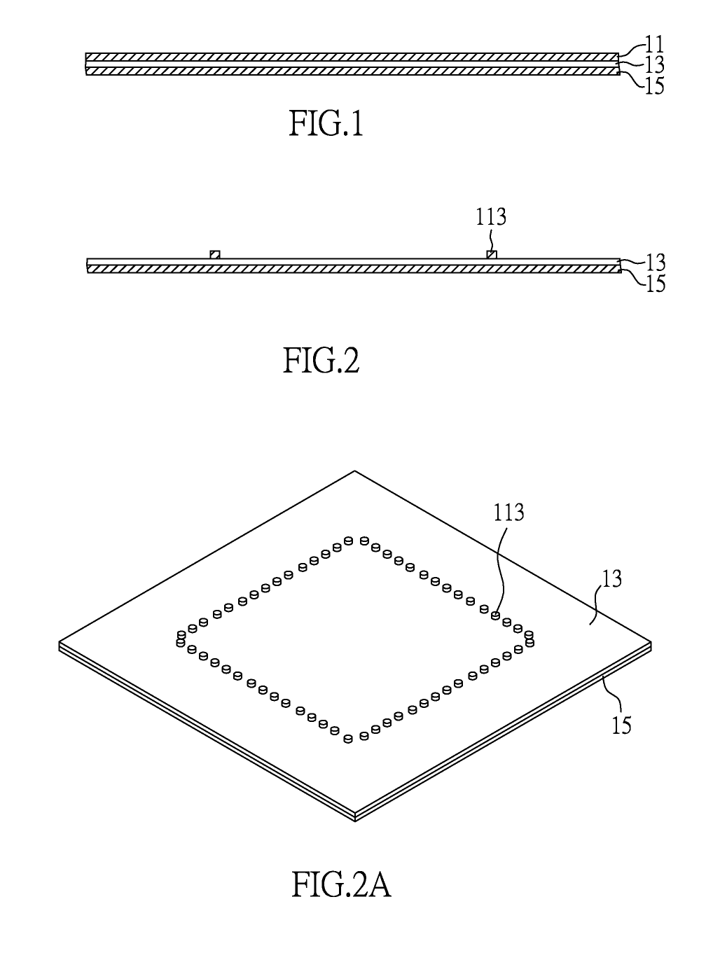

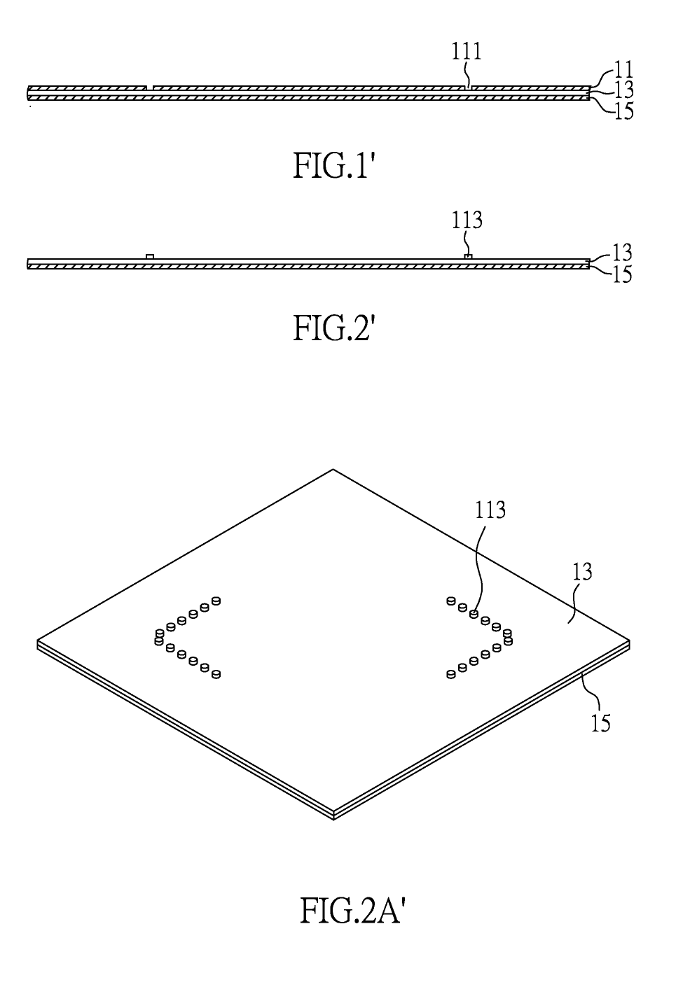

FIGS. 1-9 are cross-sectional views showing a method of making an assembly board that includes an intermediate layer, a first stopper, a first semiconductor device, a first core layer, a second stopper, a second semiconductor device, a second core layer, dual build-up circuitries and plated through holes in accordance with an embodiment of the present invention.

As shown in FIG. 9, semiconductor assembly board 100 includes intermediate layer 101, first stopper 113, first semiconductor device 31, first core layer 41, second stopper 153, second semiconductor device 33, second core layer 43, first build-up circuitry 201, second build-up circuitry 202, and plated through holes 515. First and second semiconductor devices 31, 33 are back-to-back mounted on opposite surfaces of intermediate layer 101 using first and second stoppers 113, 153 as placement guides, respectively. First stopper 113 extends from intermediate layer 101 in the upward direction and is in close proximity to peripheral edges of first semiconductor device 31. Second stopper 153 extends from intermediate layer 101 in the downward direction and is in close proximity to peripheral edges of second semiconductor device 33. First core layer 41 laterally covers first semiconductor device 31 and first stopper 113, and second core layer 43 laterally covers second semiconductor device 33 and second stopper 153. First build-up circuitry 201 covers first semiconductor device 31 and first core layer 41 in the upward direction and is electrically connected to contact pads 312 of first semiconductor device 31 through first conductive vias 217. Second build-up circuitry 202 covers second semiconductor device 33 and second core layer 43 in the downward direction and is electrically connected to contact pads 332 of second semiconductor device 33 through second conductive vias 227. Plated through holes 515 provide electrical connection between first build-up circuitry 201 and second build-up circuitry 202.

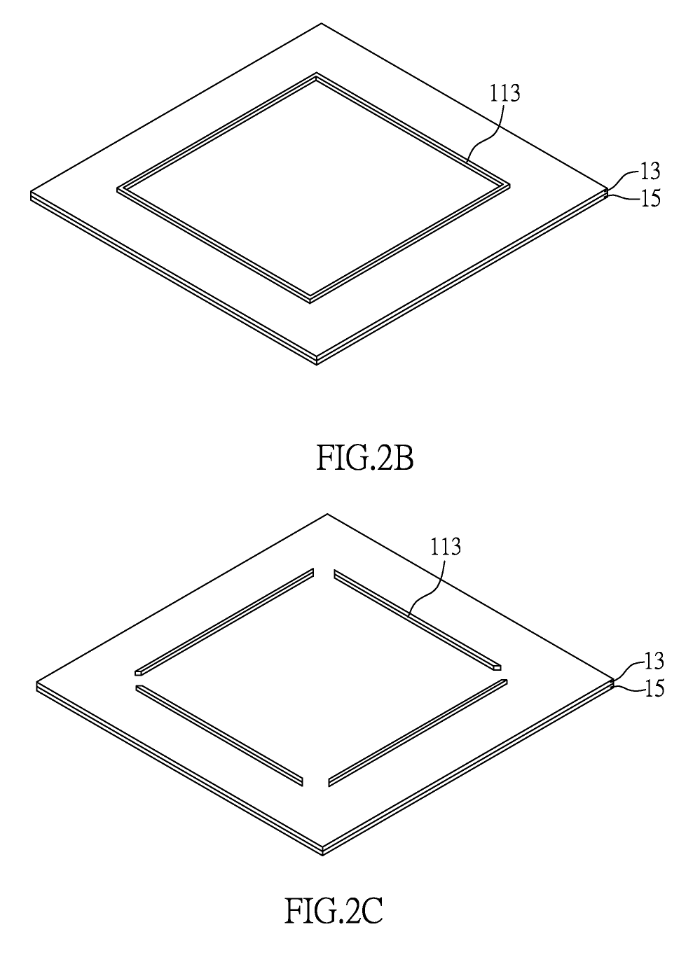

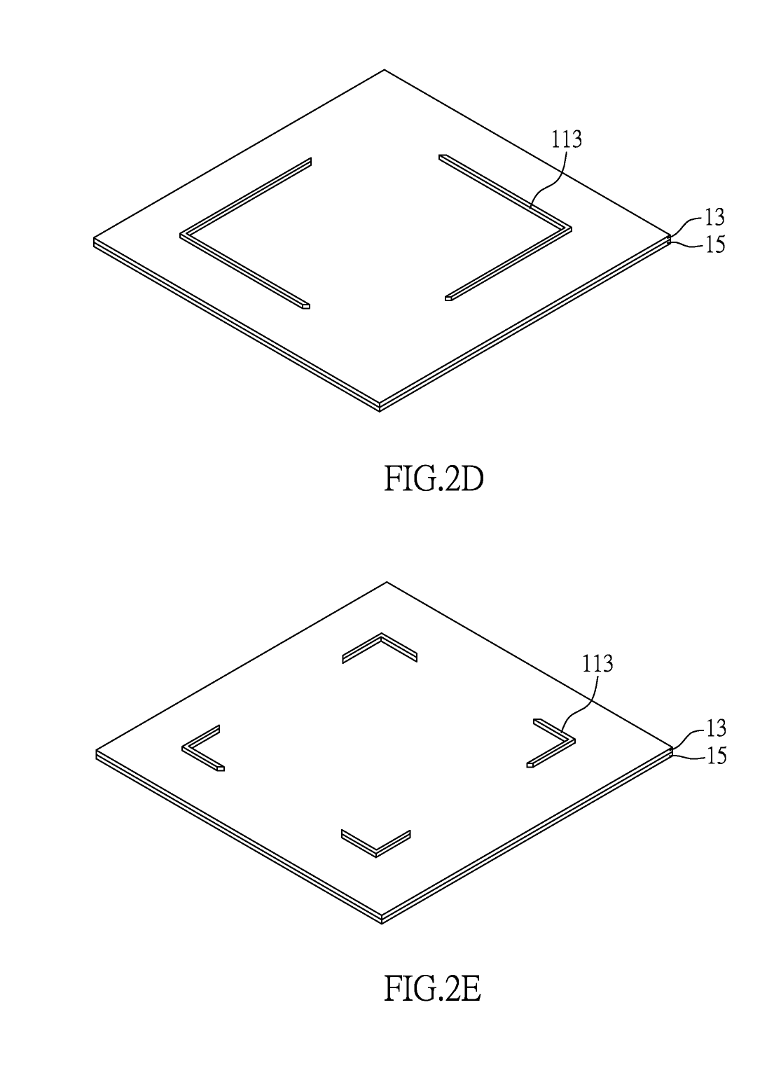

FIGS. 1 and 2 are cross-sectional views showing a process of forming a first stopper on a dielectric layer in accordance with an embodiment of the present invention, and FIG. 2A is a top perspective view corresponding to FIG. 2.

FIG. 1 is a cross-sectional view of a laminate substrate that includes first metal layer 11, dielectric layer 13 and second metal layer 15. Dielectric layer 13 is sandwiched between first metal layer 11 and second metal layer 15. Dielectric layer 13 typically is made of epoxy resin, glass-epoxy, polyimide and the like and has a thickness of 50 microns. First and second metal layers 11, 15 are each illustrated as a copper layer with a thickness of 35 microns. However, first and second metal layers 11, 15 can also be made of other various metal materials and are not limited to a copper layer. Besides, first and second metal layers 11, 15 can be deposited on dielectric layer 13 by numerous techniques including lamination, electroplating, electroless plating, evaporating, sputtering, and their combinations as a single layer or multiple layers, and preferably has a thickness in a range of 10 to 200 microns.

FIGS. 2 and 2A are cross-sectional and top perspective views, respectively, of the structure with first stopper 113 formed on dielectric layer 13. First stopper 113 can be formed by removing selected portions of first metal layer 11 using photolithography and wet etching. In this illustration, first stopper 113 consists of plural metal posts in a rectangular frame array and conforms to four sides of a semiconductor device subsequently disposed on dielectric layer 13. However, stopper patterns are not limited thereto and can be other various patterns against undesirable movement of the subsequently disposed semiconductor device.

FIGS. 1′ and 2′ are cross-sectional views showing an alternative process of forming a first stopper on a dielectric layer, and FIG. 2A′ is a top perspective view corresponding to FIG. 2′.

FIG. 1′ is a cross-sectional view of a laminate substrate with a set of cavities 111. The laminate substrate includes first metal layer 11, dielectric layer 13 and second metal layer 15 as above mentioned, and cavities 111 are formed by removing selected portions of first metal layer 11.

FIGS. 2′ and 2A′ are cross-sectional and top perspective views, respectively, of the structure with first stopper 113 formed on dielectric layer 13. First stopper 113 can be formed by dispensing or printing a photosensitive plastic material (e.g., epoxy, polyimide, etc.) or non-photosensitive material into cavities 111, followed by removing overall first metal layer 11. Herein, first stopper 113 is illustrated as an array of plural resin posts and conforms to two diagonal corners of a subsequently disposed semiconductor device.

FIGS. 2B-2E are top perspective views of other various stopper patterns for reference. For instance, first stopper 113 may consist of a continuous or discontinuous strip and conform to four sides (as shown FIGS. 2B and 2C), two diagonal corners or four corners (as shown in FIGS. 2D and 2E) of a subsequently disposed semiconductor device.

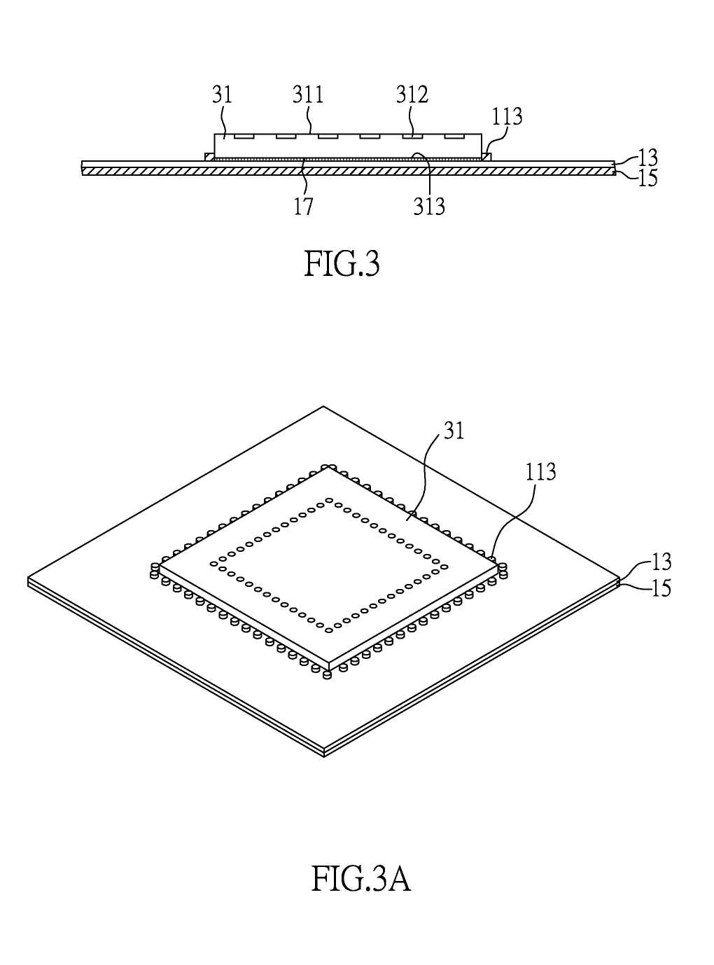

FIGS. 3 and 3A are cross-sectional and top perspective views, respectively, of the structure with first semiconductor device 31 mounted on dielectric layer 13 using first adhesive 17. First semiconductor device 31 includes active surface 311, inactive surface 313 opposite to active surface 311, and plural contact pads 312 at active surface 311. First semiconductor device 31 is mounted onto dielectric layer 13 with inactive surface 313 facing dielectric layer 13.

First stopper 113 can serve as a placement guide for first semiconductor device 31, and thus first semiconductor device 31 is precisely placed at a predetermined location. First stopper 113 extends from dielectric layer 13 and extends beyond inactive surface 313 of first semiconductor device 31 in the upward direction and is located beyond and laterally aligned with four sides of first semiconductor device 31 in the lateral directions. As first stopper 113 is in close proximity to and conforms to four lateral surfaces of first semiconductor device 31 in lateral directions and first adhesive 17 under first semiconductor device 31 is lower than first stopper 113, any undesirable movement of first semiconductor device 31 due to adhesive curing can be avoided. Preferably, a gap in between first semiconductor device 31 and first stopper 113 is in a range of about 0.001 to 1 mm.

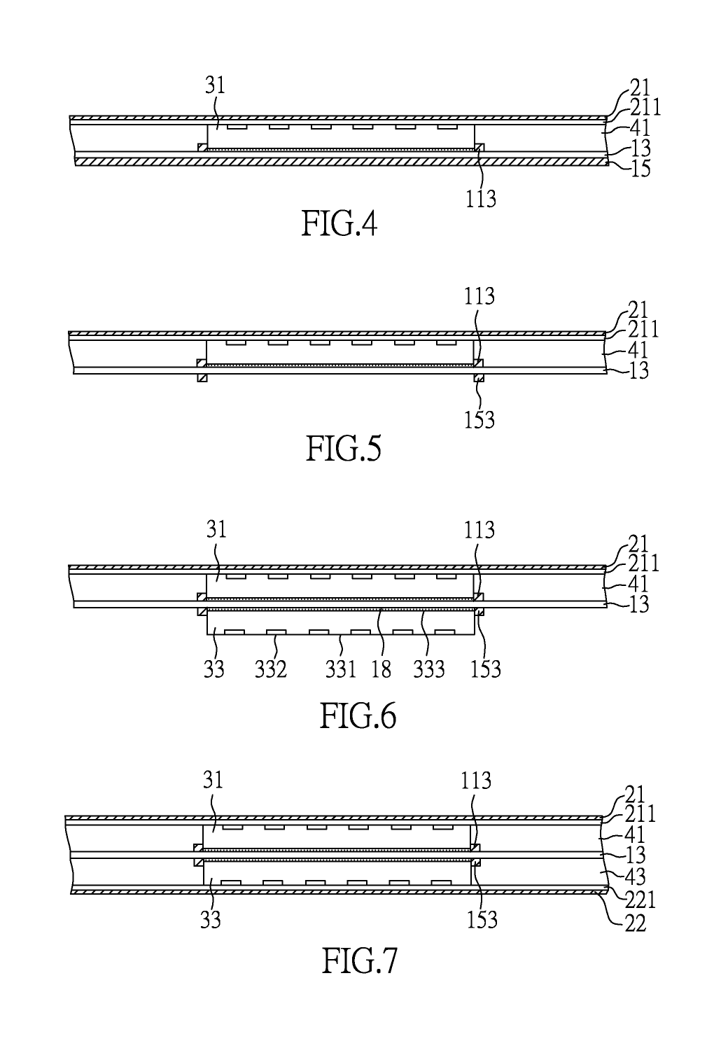

FIG. 4 is a cross-sectional view of the structure laminated with first core layer 41, first insulating layer 211 and first metal sheet 21. First core layer 41 is laminated with first semiconductor device 31, first stopper 113 and dielectric layer 13 under pressure and heat and then is solidified. As a result, first core layer 41 contacts and extends from first stopper 113 and dielectric layer 13 in the upward direction and laterally covers and surrounds and conformally coats the peripheral side surfaces of first semiconductor device 31 and first stopper 113 and extends laterally from first semiconductor device 31 and first stopper 113 to peripheral edges of the structure. First insulating layer 211 contacts and is laminated between first metal sheet 21 and first semiconductor device 31 and between first metal sheet 21 and first core layer 41. First insulating layer 211 typically has a thickness of 50 microns. First metal sheet 21 is illustrated as a copper layer with a thickness of 17 microns. Under pressure and heat, first insulating layer 211 is melt and compressed by applying downward pressure to first metal sheet 21 or/and upward pressure to second metal layer 15. Accordingly, first insulating layer 211 as solidified provides secure robust mechanical bonds between first metal sheet 21 and first semiconductor device 31 and between first metal sheet 21 and first core layer 41. First core layer 41 and first insulating layer 211 can be epoxy resin, glass-epoxy, polyimide and the like.

FIG. 5 is a cross-sectional view of the structure with second stopper 153 formed on dielectric layer 13. In this illustration, second stopper 153 is formed by removing selected portions of second metal layer 15 using photolithography and wet etching and has the pattern as illustrated in FIG. 2A. As mentioned above, second stopper 153 can also be formed by the alternative process illustrated in FIGS. 1′-2′ and be designed into other various patterns as illustrated in FIGS. 2B-2E.

FIG. 6 is a cross-sectional view of the structure with second semiconductor device 33 mounted on dielectric layer 13 using second adhesive 18. Second semiconductor device 33 includes active surface 331, inactive surface 333 opposite to active surface 331, and plural contact pads 332 at active surface 331. Second semiconductor device 33 is mounted onto dielectric layer 13 with inactive surface 333 facing dielectric layer 13.

Second stopper 153 can serve as a placement guide for second semiconductor device 33, and thus second semiconductor device 33 is precisely placed at a predetermined location. Second stopper 153 extends from dielectric layer 13 and extends beyond inactive surface 333 of second semiconductor device 33 in the downward direction and is located beyond and laterally aligned with four sides of second semiconductor device 33 in the lateral directions. As second stopper 153 is in close proximity to and conforms to four lateral surfaces of second semiconductor device 33 in lateral directions and second adhesive 18 under second semiconductor device 33 is lower than second stopper 153, any undesirable movement of second semiconductor device 33 due to adhesive curing can be avoided. Preferably, a gap in between second semiconductor device 33 and second stopper 153 is in a range of about 0.001 to 1 mm.

FIG. 7 is a cross-sectional view of the structure laminated with second core layer 43, second insulating layer 221 and second metal sheet 22. Second core layer 43 is laminated with second semiconductor device 33, second stopper 153 and dielectric layer 13 under pressure and heat and then is solidified. As a result, second core layer 43 contacts and extends from second stopper 153 and dielectric layer 13 in the downward direction and laterally covers and surrounds and conformally coats the peripheral side surfaces of second semiconductor device 33 and second stopper 153 and extends laterally from second semiconductor device 33 and second stopper 153 to peripheral edges of the structure. Second insulating layer 221 contacts and is laminated between second metal sheet 22 and second semiconductor device 33 and between second metal sheet 22 and second core layer 43. Second insulating layer 221 typically has a thickness of 50 microns. Second metal sheet 22 is illustrated as a copper layer with a thickness of 17 microns. Under pressure and heat, second insulating layer 221 is melt and compressed by applying downward pressure to first metal sheet 21 or/and upward pressure to second metal sheet 22. Accordingly, second insulating layer 221 as solidified provides secure robust mechanical bonds between second metal sheet 22 and second semiconductor device 33 and between second metal sheet 22 and second core layer 43. Second core layer 43 and second insulating layer 221 can be epoxy resin, glass-epoxy, polyimide and the like.

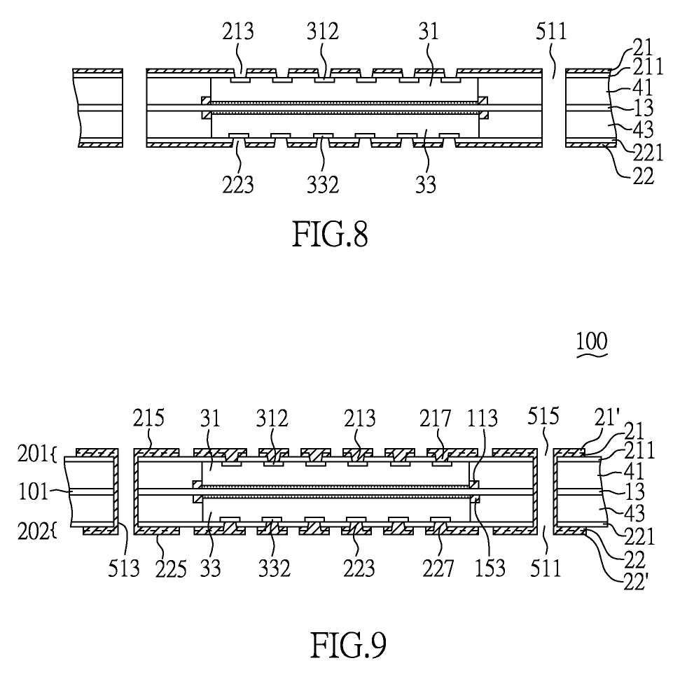

FIG. 8 is a cross-sectional view of the structure provided with first via openings 213, second via openings 223 and through holes 511. First via openings 213 extend through first metal sheet 21 and first insulating layer 211 and are aligned with contact pads 312 of first semiconductor device 31. Second via openings 223 extend through second metal sheet 22 and second insulating layer 221 and are aligned with contact pads 332 of second semiconductor device 33. First and second via openings 213, 223 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser. Through holes 511 extend through first metal sheet 21, first insulating layer 211, first core layer 41, dielectric layer 13, second core layer 43, second insulating layer 221 and second metal sheet 22 in the vertical direction. Through holes 511 are formed by mechanical drilling and can be formed by other techniques such as laser drilling and plasma etching with or without wet etching.

Referring now to FIG. 9, first conductive traces 215 and second conductive traces 225 are respectively formed on first insulating layer 211 and second insulating layer 221 by depositing first plated layer 21′ on first metal sheet 21 and into first via openings 213, depositing second plated layer 22′ on second metal sheet 22 and into second via openings 223, and then patterning first and second metal sheets 21, 22 as well as first and second plated layers 21′, 22′ thereon. Alternatively, when no first and second metal sheets 21, 22 are laminated on first and second insulating layers 211, 221 in the previous process, first and second insulating layers 211, 221 can be directly metallized to form first and second conductive traces 215, 225. First conductive traces 215 extend from first insulating layer 211 in the upward direction, extend laterally on first insulating layer 211 and extend into first via openings 213 in the downward direction to form first conductive vias 217 in direct contact with contact pads 312 of first semiconductor device 31. Second conductive traces 225 extend from second insulating layer 221 in the downward direction, extend laterally on second insulating layer 221 and extend into second via openings 223 in the upward direction to form second conductive vias 227 in direct contact with contact pads 312 of second semiconductor device 33. As a result, first and second conductive traces 215, 225 can provide signal routings for first and second semiconductor devices 31, 33.

Also shown in FIG. 9 is connecting layer 513 deposited in through holes 511 to provide plated through holes 515. Connecting layer 513 is a hollow tube that covers the inner sidewall of through holes 511 in lateral directions and extends vertically to electrically connect first conductive traces 215 and second conductive traces 225. Alternatively, connecting layer 513 can fill through holes 511. In this case, plated through holes 515 is a metal post and there is no space for an insulative filler in through holes 511.

First and second plated layer 21′, 22′ and connecting layer 513 can be deposited by numerous techniques including electroplating, electroless plating, evaporating, sputtering, and their combinations as a single layer or multiple layers. For instance, they are deposited by first dipping the structure in an activator solution to render the insulating layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form first and second conductive traces 215, 225 by numerous techniques including wet etching, electro-chemical etching, laser-assist etching, and their combinations with an etch masks (not shown) thereon that define first and second conductive traces 215, 225. Preferably, first and second plated layer 21′, 22′ and connecting layer 513 are the same material deposited simultaneously in the same manner and have the same thickness.

First and second metal sheets 21, 22, first and second plated layer 21′, 22′ and connecting layer 513 are shown as a single layer for convenience of illustration. The boundary (shown in phantom) between the metal layers may be difficult or impossible to detect since copper is plated on copper. However, the boundaries between first plated layer 21′ and first insulating layer 211, between second plated layer 22′ and second insulating layer 221, between connecting layer 513 and first insulating layer 211, between connecting layer 513 and first core layer 41, between connecting layer 513 and dielectric layer 13, between connecting layer 513 and second core layer 43, and between connecting layer 513 and second insulating layer 221 are clear.

Accordingly, as shown in FIG. 9, wiring board 100 is accomplished and includes intermediate layer 101, first stopper 113, first semiconductor device 31, first core layer 41, second stopper 153, second semiconductor device 33, second core layer 43, first build-up circuitry 201, second build-up circuitry 202 and plated through holes 515. Intermediate layer 101 is illustrated as dielectric layer 13. First and second semiconductor devices 31, 33 are back-to-back affixed on opposite sides of intermediate layer 101 at the predetermined location using first and second stoppers 113, 153 as placement guides, and are laterally covered by first and second core layers 41, 43, respectively. First build-up circuitry 201 includes first insulating layer 211 and first conductive traces 215 and provides signal routing for contact pads 312 of first semiconductor device 31. Second build-up circuitry 202 includes second insulating layer 221 and second conductive traces 225 and provides signal routing for contact pads 332 of second semiconductor device 33. Plated through holes 515 are essentially shared by intermediate layer 101, first core layer 41, second core layer 43, first build-up circuitry 201 and second build-up circuitry 202, and provide an electrical connection between the first build-up circuitry 201 and second build-up circuitry 202.

### Embodiment 2

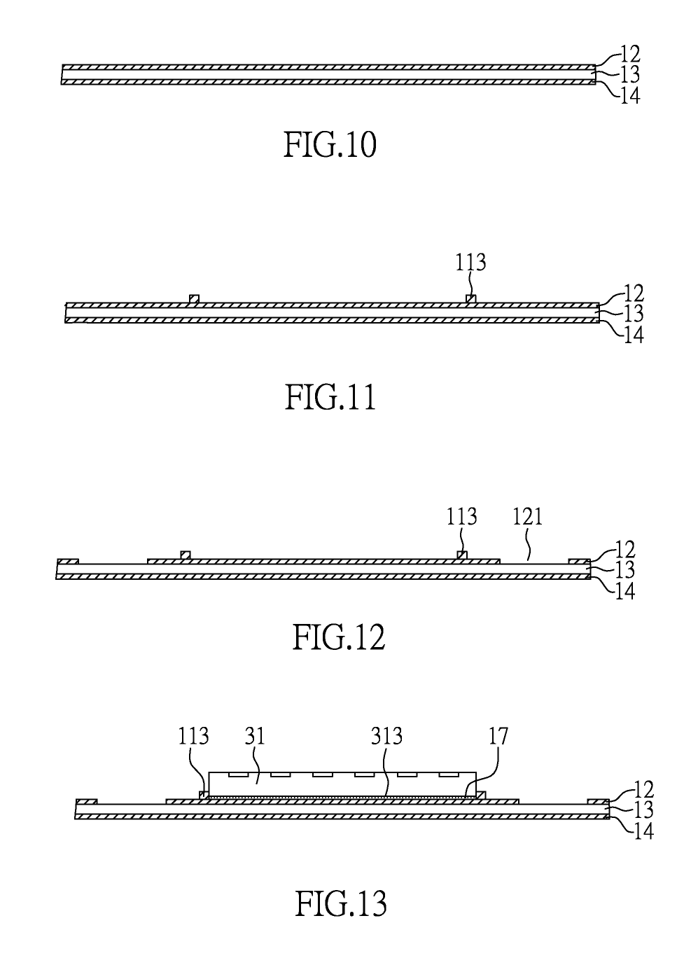

FIGS. 10-19 are cross-sectional views showing a method of making another assembly board in which embedded semiconductor devices are back-to-back mounted on a laminate substrate that includes metal layers as vertical EMI shields between the semiconductor devices in accordance with another embodiment of the present invention.

For purposes of brevity, any description in above Embodiments is incorporated herein insofar as the same is applicable, and the same description need not be repeated.

FIG. 10 is a cross-sectional view of a laminate substrate that includes first metal layer 12, dielectric layer 13 and second metal layer 14. Dielectric layer 13 is sandwiched between first metal layer 12 and second metal layer 14. First and second metal layers 12, 14 are each illustrated as a copper plate with a thickness of 35 microns.

FIG. 11 is a cross-sectional view of the structure with first stopper 113 formed on first metal layer 12. First stopper 113 can be pattern deposited on first metal layer 12 by numerous techniques including electroplating, electroless plating, evaporating, sputtering and their combinations using photolithographic process. First stopper 113 typically is made of copper, but other various metal materials are also doable. Further, first stopper 113 preferably has a thickness in a range of 10 to 200 microns. In this illustration, first stopper 113 have a thickness of 35 microns.

Subsequently, as shown in FIG. 12, openings 121 are formed through first metal layer 12 at predetermined locations for subsequent formation of plated through holes.

FIG. 13 is a cross-sectional view of the structure with first semiconductor device 31 mounted on first metal layer 12 using first adhesive 17 that is sandwiched between and contacts first metal layer 12 and first semiconductor device 31. First semiconductor device 31 is attached on first metal layer 12 with its inactive surface 313 facing first metal layer 12. Stopper 113 extends from first metal layer 12 and extends beyond inactive surface 313 of first semiconductor device 31 in the upward direction and is in close proximity to peripheral edges of first semiconductor device 31 to serve as a placement guide for first semiconductor device 31.

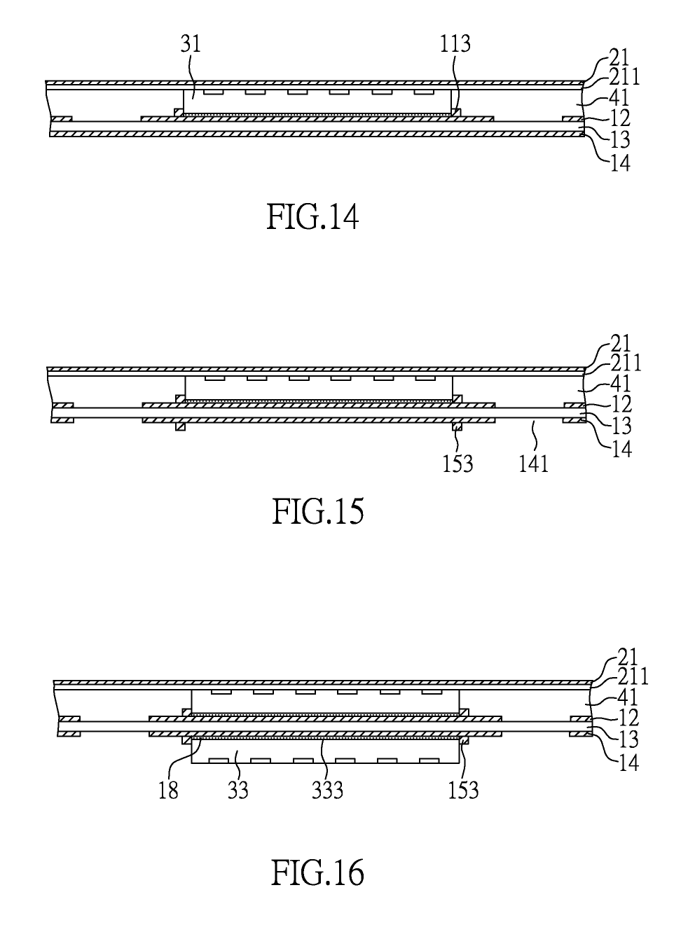

FIG. 14 is a cross-sectional view of the structure laminated with first core layer 41, first insulating layer 211 and first metal sheet 21. First core layer 41 contacts and is laminated with first semiconductor device 31, first stopper 113, first metal layer 12 and dielectric layer 13. First insulating layer 211 contacts and provides robust mechanical bonds between first metal sheet 21 and first semiconductor device 31 and between first metal sheet 21 and first core layer 41.

FIG. 15 is a cross-sectional view of the structure with second stopper 153 pattern deposited on second metal layer 14 and openings 141 formed through second metal layer 14. Second stopper 153 extends from second metal layer 14 in the downward direction. Openings 141 are formed at predetermined locations for subsequent formation of plated through holes

FIG. 16 is a cross-sectional view of the structure with second semiconductor device 33 mounted on second metal layer 14 using second adhesive 18 that is sandwiched between and contacts second metal layer 14 and second semiconductor device 33. Second semiconductor device 33 is attached on second metal layer 14 with its inactive surface 333 facing second metal layer 14. Second stopper 153 extends beyond inactive surface 333 of second semiconductor device 33 in the downward direction and is in close proximity to peripheral edges of second semiconductor device 33 to serve as a placement guide for second semiconductor device 33.

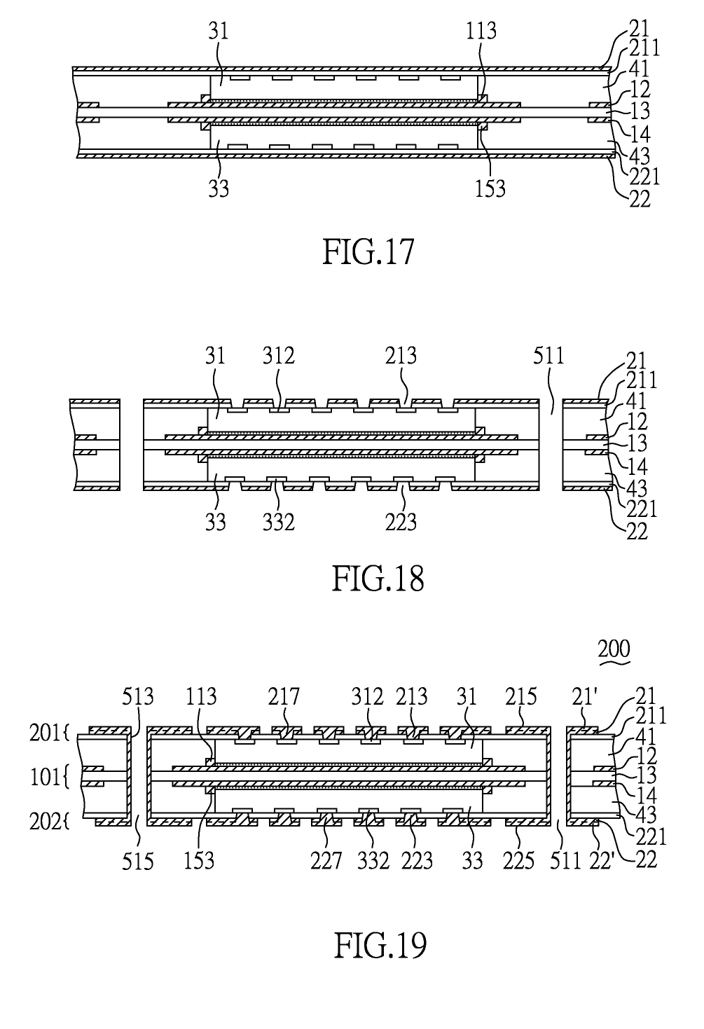

FIG. 17 is a cross-sectional view of the structure laminated with second core layer 43, second insulating layer 221 and second metal sheet 22. Second core layer 43 contacts and is laminated with second semiconductor device 33, second stopper 153, second metal layer 14 and dielectric layer 13. Second insulating layer 221 contacts and provides robust mechanical bonds between second metal sheet 22 and second semiconductor device 33 and between second metal sheet 22 and second core layer 43.

FIG. 18 is a cross-sectional view of the structure provided with first via openings 213, second via openings 223 and through holes 511. First via openings 213 extend through first metal sheet 21 and first insulating layer 211 and are aligned with contact pads 312 of first semiconductor device 31. Second via openings 223 extend through second metal sheet 22 and second insulating layer 221 and are aligned with contact pads 332 of second semiconductor device 33. Through holes 511 correspond to and are axially aligned with and concentrically positioned within openings 121, 141 in first and second metal layers 12, 14, and extend through first metal sheet 21, first insulating layer 211, first core layer 41, dielectric layer 13, second core layer 43, second insulating layer 221 and second metal sheet 22 in the vertical direction.

Referring now to FIG. 19, first conductive traces 215 and second conductive traces 225 are respectively formed on first and second insulating layers 211, 221 by depositing first plated layer 21′ on first metal sheet 21 and into first via openings 213, depositing second plated layer 22′ on second metal sheet 22 and into second via openings 223, and then patterning first and second metal sheets 21, 22 as well as first and second plated layers 21′, 22, thereon. Also, connecting layer 513 is deposited in through holes 511 to provide plated through holes 515.

Accordingly, as shown in FIG. 19, semiconductor assembly board 200 is accomplished and includes first and second semiconductor devices 31, 33 back-to-back mounted on opposite surfaces of intermediate layer 101 and shielded from vertical electromagnetic interference by first and second metal layers 12, 14 of intermediate layer 101. In this illustration, intermediate layer 101 is a laminate substrate that includes first metal layer 12, dielectric layer 13 and second metal layer 14. First and second semiconductor devices 31, 33 are respectively mounted on first metal layer 12 and second metal layer 14 using first and second stoppers 113, 153 as placement guides. As a result, first and second metal layers 12, 14 can serve as vertical EMI shields for first and second semiconductor devices 31, 33. First and second build-up circuitries 201, 202 provide signal routing for contact pads 312, 332 of first and second semiconductor devices 31, 33 through first and second conductive vias 217, 227, respectively. Plated through holes 515 provide vertical signal connection pathway between first conductive traces 215 and second conductive traces 225.

### Embodiment 3

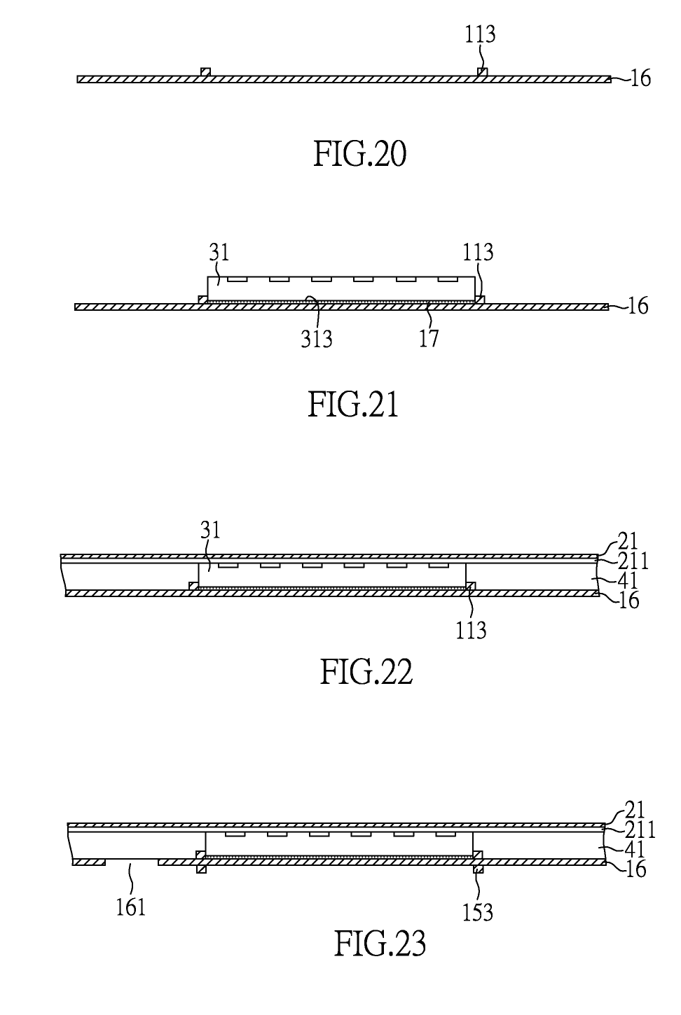

FIGS. 20-27 are cross-sectional views showing a method of making yet another assembly board in which embedded semiconductor devices are back-to-back mounted on a metal layer as a vertical EMI shield between the semiconductor devices in accordance with yet another embodiment of the present invention.

For purposes of brevity, any description in above Embodiments is incorporated herein insofar as the same is applicable, and the same description need not be repeated.

FIG. 20 is a cross-sectional view of the structure with first stopper 113 formed on metal layer 16. Metal layer 16 is illustrated as a copper plate with a thickness of 35 microns. First stopper 113 is pattern deposited on metal layer 16 and extends from metal layer 16 in the upward direction.

FIG. 21 is a cross-sectional view of the structure with first semiconductor device 31 mounted on metal layer 16 using first adhesive 17 that is sandwiched between and contacts metal layer 16 and first semiconductor device 31. First semiconductor device 31 is attached onto metal layer 16 with its inactive surface 313 facing metal layer 16. First stopper 113 extends beyond inactive surface 313 of first semiconductor device 31 in the upward direction and is in close proximity to peripheral edges of first semiconductor device 31 to serve as a placement guide for first semiconductor device 31. As a result, first semiconductor device 31 can be precisely confined at predetermined location on metal layer 16.

FIG. 22 is a cross-sectional view of the structure laminated with first core layer 41, first insulating layer 211 and first metal sheet 21. First core layer 41 contacts and is laminated with first semiconductor device 31, first stopper 113 and metal layer 16. First insulating layer 211 contacts and provides robust mechanical bonds between first metal sheet 21 and first semiconductor device 31 and between first metal sheet 21 and first core layer 41.

FIG. 23 is a cross-sectional view of the structure with second stopper 153 formed on metal layer 16. Second stopper 113 is pattern deposited on metal layer 16 and extends from metal layer 16 in the downward direction. Also shown in FIG. 23 is opening 161 formed through metal layer 16.

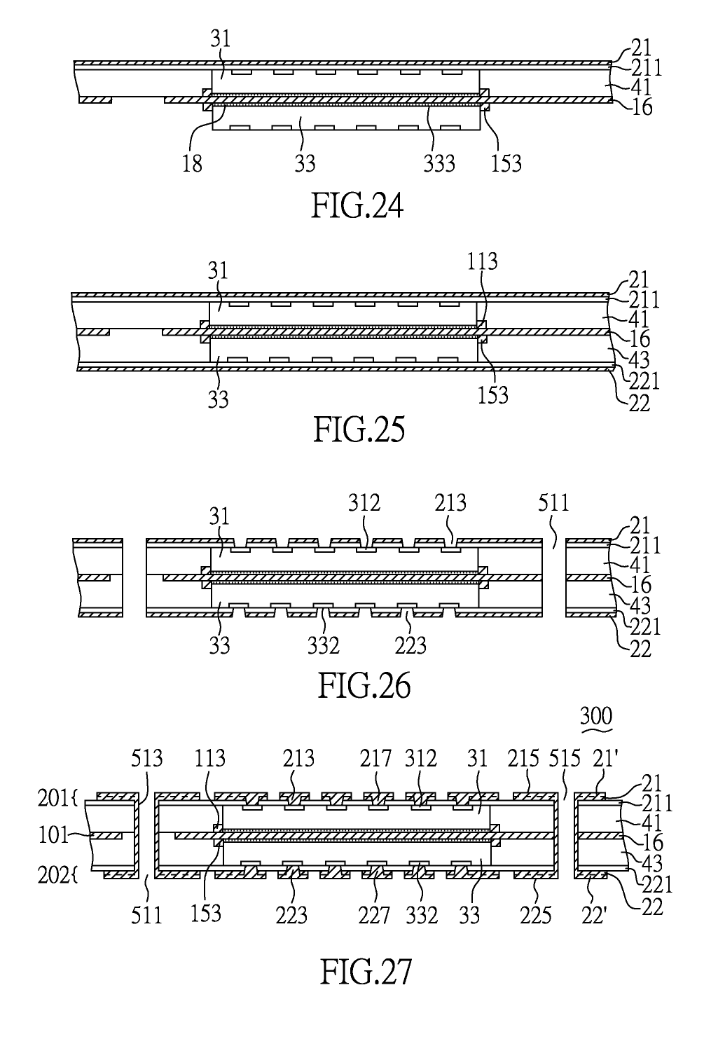

FIG. 24 is a cross-sectional view of the structure with second semiconductor device 33 mounted on metal layer 16 using second adhesive 18 that is sandwiched between and contacts metal layer 16 and second semiconductor device 33. Second semiconductor device 33 is attached onto metal layer 16 with its inactive surface 333 facing metal layer 16. Second stopper 153 extends beyond inactive surface 333 of second semiconductor device 33 in the downward direction and is in close proximity to peripheral edges of second semiconductor device 33 to serve as a placement guide for second semiconductor device 33. As a result, second semiconductor device 33 can be precisely confined at predetermined location on metal layer 16.

FIG. 25 is a cross-sectional view of the structure laminated with second core layer 43, second insulating layer 221 and second metal sheet 22. Second core layer 43 contacts and is laminated with second semiconductor device 33, second stopper 153 and metal layer 16. Second insulating layer 221 contacts and provides robust mechanical bonds between second metal sheet 22 and second semiconductor device 33 and between second metal sheet 22 and second core layer 43.

FIG. 26 is a cross-sectional view of the structure provided with first via openings 213, second via openings 223 and through holes 511. First via openings 213 extend through first metal sheet 21 and first insulating layer 211 and are aligned with contact pads 312 of first semiconductor device 31. Second via openings 223 extend through second metal sheet 22 and second insulating layer 221 and are aligned with contact pads 332 of second semiconductor device 33. Through holes 511 extend through first metal sheet 21, first insulating layer 211, first core layer 41, metal layer 16, second core layer 43, second insulating layer 221 and second metal sheet 22 in the vertical direction.

FIG. 27 is a cross-sectional view of semiconductor assembly board 300 which is accomplished by metal deposition and patterning to provide first conductive traces 215, second conductive traces 225 and plated through holes 515. First conductive traces 215 are formed on first insulating layer 211 by depositing first plated layer 21′ on first metal sheet 21 and into first via openings 213, and then patterning first metal sheet 21 as well as first plated layer 21′ thereon. Second conductive traces 225 are formed on second insulating layer 221 by depositing second plated layer 22′ on second metal sheet 22 and into second via openings 223, and then patterning second metal sheet 22 as well as second plated layer 22′ thereon. Also, connecting layer 513 is deposited in through holes 511 to provide plated through holes 515. As a result, first and second conductive traces 215, 225 of first and second build-up circuitries 201, 202 can provide signal routing for first and second semiconductor devices 31, 33 by first and second conductive vias 217, 227, and plated through holes 515 provide vertical signal connection pathway between first conductive traces 215 and second conductive traces 225. Further, metal layer 16 that serves as intermediate layer 101 between first and second semiconductor devices 31, 33 can reduce vertical EMI between first and second semiconductor devices 31, 33.

The assembly boards described above are merely exemplary. Numerous other embodiments are contemplated. In addition, the embodiments described above can be mixed-and-matched with one another and with other embodiments depending on design and reliability considerations. The assembly board can include multiple additional sets of stoppers arranged in an array for multiple additional back-to-back or/and side-by-side semiconductor devices, passive components or other electronic devices, and the build-up circuitries can include additional conductive traces to accommodate additional semiconductor devices, passive components or other electronic devices.

The semiconductor device can be a packaged or unpackaged chip. Furthermore, the semiconductor device can be a bare chip, or a wafer level packaged die, etc. The stopper can be customized to accommodate a single semiconductor device. For instance, the stopper can have a pattern that defines a square or rectangular area with the same or similar topography as a single semiconductor device.

The term “adjacent” refers to elements that are integral (single-piece) or in contact (not spaced or separated from) with one another. For instance, the contact pads of the first semiconductor device are adjacent to the first conductive traces, but not adjacent to the second conductive traces.

The term “overlap” refers to above and extending within a periphery of an underlying element. Overlap includes extending inside and outside the periphery or residing within the periphery. For instance, in the position that the first build-up circuitry faces the upward direction, the intermediate layer overlaps the second semiconductor device since an imaginary vertical line intersects the intermediate layer and the second semiconductor device, regardless of whether another element such as the adhesive is between the intermediate layer and the second semiconductor device and is intersected by the line, and regardless of whether another imaginary vertical line intersects the intermediate layer but not the second semiconductor device (outside the periphery of the second semiconductor device). Likewise, the intermediate layer overlaps the second core layer and the second core layer is overlapped by the intermediate layer. Moreover, overlap is synonymous with over and overlapped by is synonymous with under or beneath.

The term “contact” refers to direct contact. For instance, the first conductive vias contact the contact pads of the first semiconductor device but the second conductive vias do not contact the contact pads of the first semiconductor device.

The term “cover” refers to incomplete and complete coverage in a vertical and/or lateral direction. For instance, in the position that the first build-up circuitry faces the upward direction, the intermediate layer covers the second semiconductor device in the upward direction regardless of whether another element such as the adhesive is between the intermediate layer and the second semiconductor device.

The term “layer” refers to patterned and un-patterned layers. For instance, the metal layer disposed on the dielectric layer can be an un-patterned blanket sheet before photolithography and wet etching. Furthermore, a layer can include stacked layers.

The phrase “aligned with” refers to relative position between elements regardless of whether elements are spaced from or adjacent to one another or one element is inserted into and extends into the other element. For instance, the stopper is laterally aligned with the semiconductor device since an imaginary horizontal line intersects the stopper and the semiconductor device, regardless of whether another element is between the stopper and the semiconductor device and is intersected by the line, and regardless of whether another imaginary horizontal line intersects the semiconductor device but not the stopper or intersects the stopper but not the semiconductor device. Likewise, the first via opening is aligned with the contact pads of the first semiconductor device, and the second via opening is aligned with the contact pads of the second semiconductor device.

The phrase “in close proximity to” refers to a gap between elements not being wider than the maximum acceptable limit. As known in the art, when the gap between the semiconductor device and the stopper is not narrow enough, the location error of the semiconductor device due to the lateral displacement of the semiconductor device within the gap may exceed the maximum acceptable error limit. Once the location error of the semiconductor device goes beyond the maximum limit, it is impossible to align the contact pad with a laser beam, resulting in the electrical connection failure between the semiconductor device and the build-up circuitry. According to the pad size of the semiconductor device, those skilled in the art can ascertain the maximum acceptable limit for a gap between the semiconductor device and the stopper through trial and error to prevent the electrical connection failure between the semiconductor device and the build-up circuitry. Thereby, the description “the stopper is in close proximity to the peripheral edges of the semiconductor device” means that the gap between the peripheral edges of the semiconductor device and the stopper is narrow enough to prevent the location error of the semiconductor device from exceeding the maximum acceptable error limit.

The phrases “mounted on”, “attached on”, “attached onto”, “laminated on” and “laminated with” include contact and non-contact with a single or multiple support element(s). For instance, the first semiconductor device can be mounted on the intermediate layer regardless of whether it contacts the intermediate layer or is separated from the intermediate layer by an adhesive.

The phrases “electrical connection” or “electrically connects” and “electrically connected” refer to direct and indirect electrical connection. For instance, the plated through hole provides an electrical connection for first conductive trace regardless of whether it is adjacent to the first conductive trace or electrically connected to the first conductive trace by the third conductive trace.

The term “above” refers to upward extension and includes adjacent and non-adjacent elements as well as overlapping and non-overlapping elements. For instance, in the position that the first build-up circuitry faces the downward direction, the first stopper extends above, is adjacent to and protrudes from the intermediate layer.

The term “below” refers to downward extension and includes adjacent and non-adjacent elements as well as overlapping and non-overlapping elements. For instance, in the position that the first build-up circuitry faces the upward direction, the intermediate layer extends below the first semiconductor device in the downward direction regardless of whether the intermediate layer is adjacent to first the semiconductor device.

The “first vertical direction” and “second vertical direction” do not depend on the orientation of the assembly board, as will be readily apparent to those skilled in the art. For instance, the active surface of the first semiconductor device faces the first vertical direction and the active surface of the second semiconductor device faces the second vertical direction regardless of whether the assembly board is inverted. Likewise, the stopper is “laterally” aligned with the semiconductor device in a lateral plane regardless of whether the assembly board is inverted, rotated or slanted. Thus, the first and second vertical directions are opposite one another and orthogonal to the lateral directions, and a lateral plane orthogonal to the first and second vertical directions intersects laterally aligned elements. Furthermore, the first vertical direction is the downward direction and the second vertical direction is the upward direction in the position that the active surface of the first semiconductor device faces the downward direction and the active surface of the second semiconductor device faces the upward direction, and the first vertical direction is the upward direction and the second vertical direction is the downward direction in the position that the active surface of the first semiconductor device faces the upward direction and the active surface of the second semiconductor device faces the downward direction.

The assembly board according to the present invention has numerous advantages. For instance, the stoppers can be a perfect placement guide for the semiconductor devices back-to-back embedded in the assembly board. As the semiconductor devices are bonded to the intermediate layer by adhesive, any movement due to placement error or adhesive reflow during curing can be avoided. Therefore, the assembly board is reliable, inexpensive and well-suited for high volume manufacture. Further, the back-to-back embedded structure reduces total thickness of the assembly. The direct electrical connection without solder between the semiconductor device and the build-up circuitry is advantageous to high I/O and high performance. Vertical connection for 3D stacking through plated through holes and build-up layers reduces cost and ensures reliability.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A semiconductor assembly board with back-to-back embedded semiconductor devices, comprising:
an intermediate layer;
a first semiconductor device that is mounted on the intermediate layer by a first adhesive and includes an active surface with a contact pad thereon and an inactive surface opposite to the active surface, wherein the active surface faces a first vertical direction away from the intermediate layer and the inactive surface faces a second vertical direction toward the intermediate layer;
a first stopper that extends from the intermediate layer in the first vertical direction and serves as a placement guide for the first semiconductor device and is in close proximity to and laterally aligned with peripheral edges of the first semiconductor device in lateral directions orthogonal to the vertical directions;
a second semiconductor device that is mounted on the intermediate layer by a second adhesive and includes an active surface with a contact pad thereon and an inactive surface opposite to the active surface, wherein the active surface faces the second vertical direction away from the intermediate layer and the inactive surface faces the first vertical direction toward the intermediate layer;
a second stopper that extends from the intermediate layer in the second vertical direction and serves as a placement guide for the second semiconductor device and is in close proximity to and laterally aligned with peripheral edges of the second semiconductor device in lateral directions orthogonal to the vertical directions;
a first core layer that laterally covers the first semiconductor device and the first stopper;
a second core layer that laterally covers the second semiconductor device and the second stopper;
a first build-up circuitry that covers the first semiconductor device and the first core layer from the first vertical direction and is electrically connected to the contact pad of the first semiconductor device through a first conductive via;
a second build-up circuitry that covers the second semiconductor device and the second core layer from the second vertical direction and is electrically connected to the contact pad of the second semiconductor device through a second conductive via; and
a plated through hole that extends through the first core layer, the intermediate layer and the second core layer to provide an electrical connection between the first build-up circuitry and the second build-up circuitry.

2. The semiconductor assembly board of claim 1, wherein the intermediate layer is a dielectric layer or a metal layer.

3. The semiconductor assembly board of claim 1, wherein the intermediate layer is a laminate substrate that includes a first metal layer, a second metal layer, and a dielectric layer sandwiched between the first metal layer and the second metal layer.

4. The semiconductor assembly board of claim 1, wherein the first stopper and the second stopper are individually formed by patterning of a metal layer on the intermediate layer or by pattern deposition of a metal or a plastic material on the intermediate layer.

5. The semiconductor assembly board of claim 1, wherein the first stopper and the second stopper individually include a continuous or discontinuous strip or an array of posts.

6. The semiconductor assembly board of claim 1, wherein the stopper is made of a metal or a photosensitive plastic material.

7. The semiconductor assembly board of claim 1, wherein gaps in between the first semiconductor device and the first stopper and between the second semiconductor device and the second stopper are in a range of 0.001 to 1 mm.

8. The semiconductor assembly board of claim 1, wherein the first stopper and the second stopper individually have a height in a range of 10 to 200 microns.

9. The semiconductor assembly board of claim 1, wherein the first adhesive contacts and is coplanar with the first stopper in the second vertical direction and is lower than the first stopper in the first vertical direction, and the second adhesive contacts and is coplanar with the second stopper in the first vertical direction and is lower than the second stopper in the second vertical direction.
